(19) United States
(12) Patent Application Publication
(10) Pub. No.: US 2011/0024720 A1
(43) Pub. Date: Feb. 3, 2011

(54) High-efficiency LED

(75) Inventors: Jui-Hung Chen, Taoyuan City (TW); Pei-Hsuan Lan, Banciao City (TW); Yu-Bing Lan, Banciao City (TW)

Correspondence Address: BACON & THOMAS, PLLC, 625 SLATERS LANE, FOURTH FLOOR, ALEXANDRIA, VA, 22314-1176, US

(73) Assignee: Forward Electronics Co., Ltd., Taipei City (TW)

(21) Appl. No.: 12/588,129

(22) Filed: Oct. 6, 2009

(30) Foreign Application Priority Data
Aug. 3, 2009 (TW) 098126051

(51) Int. Cl. H01L 33/00

(52) U.S. Cl. 257/13; 257/98; 257/E33.008; 257/E33.074; 977/755

(57) ABSTRACT

A high-efficiency LED includes: a substrate, an epitaxial layer structure, a cathode, an anode, a transparent sealing compound and a polyimide layer. The polyimide layer covers surfaces of the epitaxial layer structure and the substrate. The transparent sealing compound covers the polyimide layer, the substrate, the epitaxial layer structure, the cathode and the anode. The polyimide layer of the present invention has a refractive index higher than that of packaging materials in prior art, so as to reduce total internal reflection and optical consumption caused by light scattered from the epitaxial layer structure and the transparent sealing compound.

### BACKGROUND OF THE INVENTION

1. Field of the Invention

The invention relates generally to an LED and, more particularly, to a high-efficiency LED for significantly increasing light emitting efficiency.

2. Description of Related Art

Generally, the optical efficiency of Light Emitting Diode (LED) is classified into an internal quantum efficiency and an external optical extraction efficiency. The internal quantum efficiency is known as an electro-optical conversion efficiency in a semiconductor chip. Typically, the internal quantum efficiency is relatively high but its efficiency is dependent on the technical capability of LED chip manufacturing factory. On the other hand, the external optical extraction efficiency is relatively low, which is usually the main reason why the overall light emitting efficiency of the LED cannot be upgraded.

The low optical extraction efficiency is resulted from a total internal reflection caused by different media, which limits light within LED without effectively emitting out. According to the Snell's law, light injected into different media would generate reflection and refraction. There are an incident light and a refractive light in the same plane, and the relation between the incident angle of the incident light and the refractive angle of the refractive light satisfies the following equation:

n₁ sin θ₁=n₂ sin θ₂,

where n₁ and n₂ are refractive indexes of incident and refraction media respectively, θ₁ and θ₂ are angles of incident and refraction, known as incident angle and refractive angle. It would generate a total internal reflection when light entering from more optically dense medium (higher refractive index) into less optically dense medium (lower refractive index) have an incident angle greater than a critical angle θ_{c}. The critical angle θ_{c} is calculated from the following equation:

θ_{c}=arcsin(n₂/n₁).

Typically, the refractive index of LED chip material is about 2.4-2.8, while the epoxy material commonly used for packaging LED has a refractive index of about 1.54, and the silicone has a refractive index of about 1.41-1.54, both being lower than the refractive index of LED chip material. When light is emitted from LED chip with higher refractive index to LED packaging material with lower refractive index, it is inevitable to cause a total internal reflection within LED, which results in a low extraction efficiency.

Taking the LED shown in FIG. 1 as an example, the LED includes: a transparent sealing compound 10, a substrate 21, an epitaxial layer structure 22, a first electrode 23 and a second electrode 24. The epitaxial layer structure 22 is formed on the substrate 21, and the transparent sealing compound 10 covers the substrate 21, the epitaxial layer structure 22, the first electrode 23 and the second electrode 24. The substrate 21 and the epitaxial layer structure 22 have a refractive index of about 2.4-2.8, and the transparent sealing compound 10 has a refractive index of about 1.41-1.54. Therefore, according to the Snell's law, it would generate a total internal reflection when light is emitted from the substrate 21 and the epitaxial layer structure 22 into the transparent sealing compound 10. As a result, light is restricted within LED and is absorbed by the LED material, which will generate heat energy in the LED and thus reduce lifetime and efficiency of the LED.

Therefore, it is desirable to provide a high-efficiency LED to mitigate and/or obviate the aforementioned problems.

### SUMMARY OF THE INVENTION

The object of the present invention is to provide a high-efficiency LED for effectively reducing the total internal reflection within the LED and increasing the light emitting efficiency.

In accordance with one aspect of the invention, there is provided a high-efficiency LED, which comprises: a substrate; an epitaxial layer structure formed on the substrate, the epitaxial layer structure including an active layer, a first position and a second position; a first electrode arranged on the first position of the epitaxial layer structure; a second electrode arranged on the second position of the epitaxial layer structure; a polyimide layer covering the epitaxial layer structure and the substrate, whereby lights emitted from the epitaxial layer structure pass through the polyimide layer for scattering.

In accordance with another aspect of the invention, there is provided a high-efficiency LED, which comprises: a conductive substrate; an epitaxial layer structure formed on the conductive substrate; a first electrode arranged on the epitaxial layer structure; a second electrode arranged on the conductive substrate; a polyimide layer covering the epitaxial layer structure and the conductive substrate, whereby lights emitted from the epitaxial layer structure pass through the polyimide layer for scattering.

### BRIEF DESCRIPTION OF THE DRAWINGS

FIG. 1 is a schematic view of a conventional LED;

FIG. 2 schematically illustrates a high-efficiency LED in accordance with a preferred embodiment of the present invention;

FIG. 3 illustrates the chemical formula of the polyimide layer in accordance with a preferred embodiment of the present invention;

FIG. 4 schematically illustrates a high-efficiency LED in accordance with another preferred embodiment of the present invention; and

FIG. 5 illustrates the physical structure of the polyimide layer in accordance with the present invention.

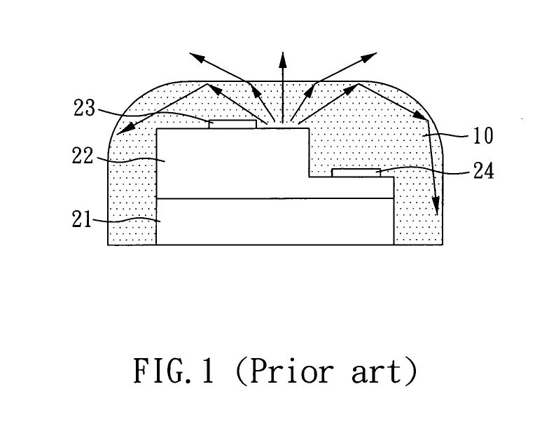

### DETAILED DESCRIPTION OF THE PREFERRED EMBODIMENT

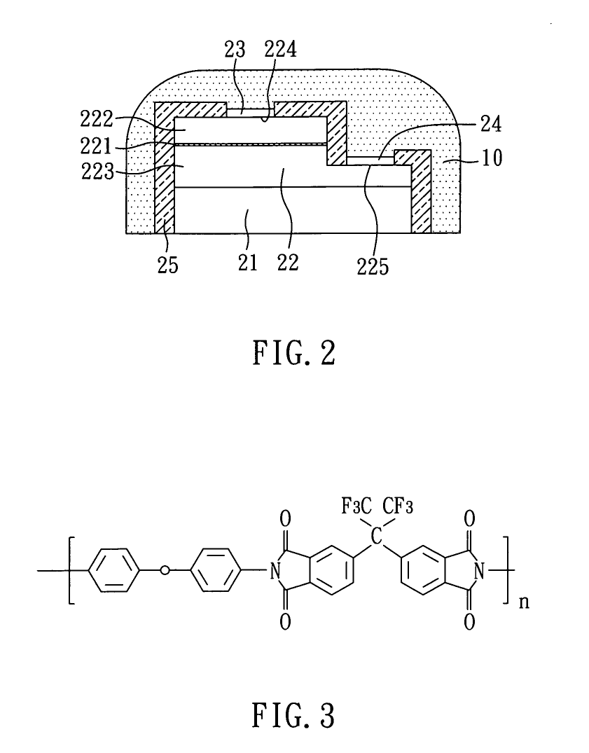

With reference to FIG. 2, there is shown a high-efficiency LED in accordance with the present invention. The high-efficiency LED comprises: a substrate 21, an epitaxial layer structure 22 formed on the substrate 21, a first electrode 23, a second electrode 24 and a polyimide layer 25. The epitaxial layer structure 22 includes an active layer 221, a P-type semiconductor layer 222, an N-type semiconductor layer 223, a first position 224 and a second position 225. The first electrode 23 is formed on the first position 224 of the epitaxial layer structure 22, and the second electrode 24 is formed on the second position 225 of the epitaxial layer structure 22. Preferably, the active layer 221 is a multi-quantum well formed between the P-type semiconductor layer 222 and the N-type semiconductor layer 223. In an embodiment of the present invention, the first electrode 23 is an anode connected to the P-type semiconductor layer 222, and the second electrode 24 is a cathode connected to the N-type semiconductor layer 223. In addition, the high-efficiency LED of the present invention further comprises a transparent sealing compound 10 for covering the substrate 21, the epitaxial layer structure 22, the first electrode 23, the second electrode 24 and the polyimide layer 25.

As shown in FIG. 2, the high-efficiency LED of the present invention is characterized in that the polyimide layer 25 is inlaid between the substrate 21 and epitaxial layer structure 22, and the transparent sealing compound 10. The polyimide layer 25 is composed of polyimide molecules as shown in FIG. 3, which have an adjustable refractive index of 1.6-1.9 in visible light region. In comparison with a relative low light emitting through out caused by the LED packaging material with refractive index of 1.41-1.54 and the inner chip material with refractive index of 2.4-2.8 in prior art, the polyimide layer 25 in the present invention has a higher refractive index to mitigate total internal reflection occurred at the interface of the substrate 21, the epitaxial layer structure 22 and the transparent sealing compound 10, thereby ultimately allowing more lights to pass through the transparent sealing compound 10.

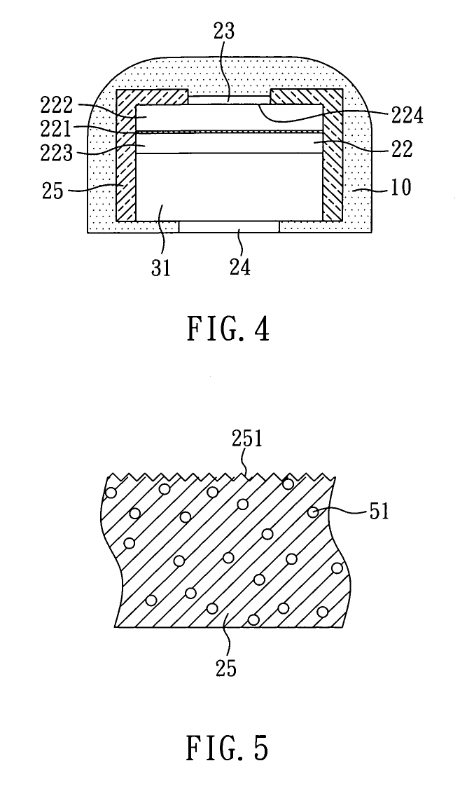

Further, with reference to FIG. 4, there is shown another embodiment of high-efficiency LED in accordance with the present invention. The high-efficiency LED comprises: a conductive substrate 31, an epitaxial layer structure 22 formed on the conductive substrate 31, a first electrode 23, a second electrode 24 and a polyimide layer 25. The epitaxial layer structure 22 includes an active layer 221, a P-type semiconductor layer 222 and an N-type semiconductor layer 223. The first electrode 23 is formed on the epitaxial layer structure 22, and the second electrode 24 is formed on the conductive substrate 31. Preferably, the active layer 221 is a multi-quantum well formed between the P-type semiconductor layer 222 and the N-type semiconductor layer 223. The high-efficiency LED of the present invention further comprises a transparent sealing compound 10 for covering the substrate 21, the epitaxial layer structure 22, the first electrode 23, the second electrode 24 and the polyimide layer 25.

As shown in FIG. 4, the high-efficiency LED of the present invention is characterized in that the polyimide layer 25 is inlaid between the conductive substrate 31 and epitaxial layer structure 22, and the transparent sealing compound 10. The polyimide layer 25 is composed of polyimide molecules, which have an adjustable refractive index of 1.6-1.9 in visible light region. In comparison with a relative low light scattering caused by the LED packaging material with refractive index of 1.41-1.54 and the inner chip material with refractive index of 2.4-2.8 in prior art, the polyimide layer 25 in the present invention has a higher refractive index to mitigate the total reflection occurred at the junctions of the conductive substrate 31, the epitaxial layer structure 22 and the transparent sealing compound 10, thereby ultimately allowing more light to pass through the transparent sealing compound 10.

Moreover, with reference to FIG. 5, the polyimide layer 25 of the present invention further includes particles selected from the group consisting of TiO2, ZnO, Nb2O5, Ta2O5, Zr2O2, Si, GaP. The surface 251 of the polyimide layer 25 can be formed as a micro-structure or surface roughness for further increasing the light emitting efficiency.

Although the present invention has been explained in relation to its preferred embodiment, it is to be understood that many other possible modifications and variations can be made without departing from the scope of the invention as hereinafter claimed.

What is claimed is:

1. A high-efficiency LED comprising:
a substrate;
an epitaxial layer structure formed on the substrate, the epitaxial layer structure including an active layer, a first position and a second position;
a first electrode arranged on the first position of the epitaxial layer structure;
a second electrode arranged on the second position of the epitaxial layer structure;
a polyimide layer covering the epitaxial layer structure and the substrate, whereby light emitted from the epitaxial layer structure passes through the polyimide layer.

2. The high-efficiency LED of claim 1, wherein the epitaxial layer structure includes an N-type semiconductor layer and an P-type semiconductor layer, the active layer is disposed between the N-type semiconductor layer and the P-type semiconductor layer, the first electrode is connected to the N-type semiconductor layer and the second electrode is connected to the P-type semiconductor layer.

3. The high-efficiency LED of claim 2, wherein the first electrode is a cathode.

4. The high-efficiency LED of claim 2, wherein the second electrode is an anode.

5. The high-efficiency LED of claim 1, further comprising a transparent sealing compound for covering the epitaxial layer structure, the substrate, the first electrode, the second electrode and the polyimide layer.

6. The high-efficiency LED of claim 1, wherein the polyimide layer is formed by polyimide molecules.

7. The high-efficiency LED of claim 1, wherein the polyimide layer further includes particles selected from the group consisting of TiO2, ZnO, Nb2O5, Ta2O5, Zr2O2, Si and GaP.

8. The high-efficiency LED of claim 1, wherein the polyimide layer has a surface formed as a micro-structure or surface roughness.

9. The high-efficiency LED of claim 1, wherein the active layer of the epitaxial layer structure is a multi-quantum well.

10. A high-efficiency LED comprising:
a conductive substrate;
an epitaxial layer structure formed on the conductive substrate;
a first electrode arranged on the epitaxial layer structure;
a second electrode arranged on the conductive substrate;
a polyimide layer covering the epitaxial layer structure and the conductive substrate, whereby light emitted from the epitaxial layer structure passes through the polyimide layer for scattering.

11. The high-efficiency LED of claim 10, wherein the epitaxial layer structure includes an N-type semiconductor layer, an P-type semiconductor layer, and an active layer disposed between the N-type semiconductor layer and the P-type semiconductor layer.

12. The high-efficiency LED of claim 10, wherein the active layer of the epitaxial layer structure is a multi-quantum well.

13. The high-efficiency LED of claim 10, further comprising a transparent sealing compound for covering the epitaxial layer structure, the conductive substrate, the first electrode, the second electrode and the polyimide layer.

14. The high-efficiency LED of claim 10, wherein the polyimide layer is formed by polyimide molecules.

15. The high-efficiency LED of claim 10, wherein the polyimide layer further includes particles selected from the group consisting of TiO2, ZnO, Nb2O5, Ta2O5, Zr2O2, Si and GaP.

16. The high-efficiency LED of claim 10, wherein the polyimide layer has a surface formed as a micro-structure or surface roughness.
